(19) United States
(12) Patent Application Publication
(10) Pub. No.: US 2005/0056311 A1
(43) Pub. Date: Mar. 17, 2005

(54) Miniature thermal-photoelectric power supply

(76) Inventor: Pham Ky Son, Ho Chi Minh City (VN)

Correspondence Address: STEINBERG & RASKIN, P.C., 1140 AVENUE OF THE AMERICAS, 15th FLOOR, NEW YORK, NY, 10036-5803, US

(21) Appl. No.: 10/938,987

(22) Filed: Sep. 10, 2004

(30) Foreign Application Priority Data
Sep. 11, 2003 (VN) 1-2003-00791

(51) Int. Cl. H01L 35/30

(52) U.S. Cl. 136/205

(57) ABSTRACT

The present invention relates to a miniature thermal-photoelectric power supply in order to equip the mobile devices, such as, laptops, mobile phones, and the like, with the power supply which is compact, lightweight but relatively large storage capacity. In miniature thermal-photoelectric power supply in accordance with the invention, a high energy level can be stored as the heat energy in a heat energy storing layer in the form of a thin chamber containing gas CO₂ in critical state. When an exciting current is applied, this stored heat energy will be taken up by means of Peltier effect, thereby releasing and converting said stored energy into light during the current discharging through an inert gas layer. The light radiates on the surface of a photoelectric cell and can be absorbed and converted into electric energy. This produced electric energy is sufficient for supplying to the inside circuit of the miniature power supply and the loading circuit of a mobile device for an extended operation period of time.

### FIELD OF THE INVENTION

This invention relates to a miniature power supply, more particularly, to the miniature thermal-photoelectric power supply for supplying electric power to several compact electronics, such as, laptops, mobile phones, personal digital assistants, and other devices, e.g., digital cameras and the like.

### BACKGROUND OF THE INVENTION

Nowadays, batteries or secondary batteries have been widely used as power supplies for the mobile devices, such as, mobile phones or the like. The working principle of the batteries is well-known for decades, wherein they discharge to provide electrical power, and then recharge later on. In principle, each battery generally comprises two positive and negative plates and these electrode plates are separated with an insulating solvent. In charging, an external power source is connected to two electrode plates of the battery in order to supply energy for the chemico-physical conversion between two electrode plates and the insulator, and as a result, electrons and cations accumulate at the negative plate and the positive plate, respectively. Due to the accumulation, there is a voltage between two electrode plates and the electric energy which is stored in the battery will be used for supplying to the load electric circuits of the mobile devices for use in their operation process. Basically, the stored electric power depends on the materials, dimensions and weight of the electrode plates. In particular, Ni-MH and Fe—Cd batteries have energy density in the range of 60 to 90 W.h/kg, the energy density of a Lithium ion (Li-ion) battery is in the range of 150 to 200 W.h/kg, and in the latest generation of battery based on Li-polyme the energy density is about of 200 to 300 W.h/kg. Disadvantages with these types batteries include their dimensions are relatively large and it is required a long time during their charging process. Thus, to meet the requirements in relation with the usage of the mobile devices in an extended period, it is necessary to use the batteries which are bulky and heavy. It is to be appreciated, however, this is not appropriate because of the basic need for the batteries are compact structure and the short period of time during charging when they are used in the mobile devices in the communications field. Thus, a problem should be solved in the device and related element manufacture industry of the communications technology wherein there is a need of an alternative type of power supply with large storage capacity, compact structure and can be charged quickly to satisfy the increasing demand of mobile devices in the future.

### SUMMARY OF THE INVENTION

In view of above mentioned, it is an object of the present invention to provide a new generation power supply has storage capacity which not depends directly on its dimensions and weight. The power supply in accordance with the present invention, therefore, can be produced very compact with a large storage capacity appropriate for the existing mobile devices.

To this end, the present invention provides a miniature thermal-photoelectric power supply with above-described specific advantages since the miniature power supply has structure and working principle which are fully different from those of commonly known batteries in the art. In conventional batteries, electric energy is stored in the form of the accumulation of electrons and cations in two electrode plates of the battery, respectively, whilst in the miniature thermal-photoelectric power supply in accordance with the invention, the energy is stored as thermal energy in a “latent” heat layer of the power supply.

In a preferred aspect, the present invention discloses a miniature thermal-photoelectric power supply comprising:
a heat energy storing layer substantially is a thin chamber containing gas CO₂ in critical state, wherein a metal net which is capable of highly heat-radiating is disposed within gas CO₂ in chamber during the thermal energy charge process by connecting to an external power source;
a heat taking-up and conversion into the light energy layer is coupled to said heat energy storing layer for taking-up and converting the heat energy stored in said heat energy storing layer into the electric energy, this layer comprises:
   a taking-up heat layer including a welded joint interposed between a copper substrate and a plurality of membranes of a n-type semiconductor, wherein due to Peltier effect, when a flow of electrons is passed from the copper substrate to the n-type material membranes, the junction is warmed or cooled depending on the direction of the flow of electrons, particularly, the temperature of copper substrate is lowered since the electrons absorb the energy from the junction and pass across the band gap of n-type semiconductor, and by means of a temperature difference between the copper substrate and the heat-absorption layer, a heat flow flows from the heat-absorption layer with a higher temperature to the copper substrate which emits heat continuously;
   a converting supplied electric energy and taken-up energy into light layer includes an inert gas layer is contained in a thin chamber such that when a flow of electrons flowing from n-type material membranes discharge across the inert gas layer to copper electrode, Plasma phenomenon occurs wherein energy of electrons in the gas layer which is much lower than energy level at the conduction band of n-type semiconductor will be dropped to a lower energy level, thereby the energy of electrons will be converted into the light energy;
   a thin quartz plate acts as a lid of said inert gas chamber to enable the light to pass through;
   a photoelectric cell plate coupled to said thin quartz plate for receiving and converting the light into the electric energy which will be supplied to an external load device; and
a cooling layer of photoelectric cell plate simultaneously serves as a heat recovery layer.

Next, a detailed explanation of the working principle of miniature power supply in accordance with the invention will be described.

When there is a need of power supplying to the load circuit of one mobile device, an exciting current firstly is applied to the electric circuit of the miniature power supply. This exciting current runs to the surface of the material layer in contact with said heat-absorption layer and causes the heat stored in the heat-absorption layer to be taken-up to an upper layer, wherein the total energy which was taken-up will be released as the light energy. Light is radiated on a photocathode surface of the photoelectric cell plate and is converted into the current energy. Output electric energy amount of the miniature thermal-photoelectric power supply of the present invention should be made higher than input electric energy amount which is applied to the inside circuit of the power supply. The required electric energy amount is supplied to maintain the operation of the miniature thermal-photoelectric power supply. The remaining electric energy at output of the miniature power supply is used in order to feed the load circuit of a mobile device. The important conditions are demanded for allowing the miniature power supply to operate as follows:
Quantum absorption yield of the photoelectric cell plate is needed to be relatively high to obtain an electric energy level at output of the miniature power supply which is sufficient for feeding energy to the electric circuits of the power supply as well as those of a mobile device.
The circuit of miniature power supply should be provided with a heat taking-up rate sufficiently high such that the energy level which is carried by means of the electric current to the upper surface of this layer and released as the light should be sufficient for applying to the photoelectric cell in order to generate a current which satisfy the above-mentioned requirement.
The amount of heat energy which is stored in the heat-absorption layer should be high enough for supplying to the conversion process of the heat energy into current energy, and this current level should be adequate to the demand of the circuits of a mobile device for a long period of time.

Other characteristics and advantages of the invention will become clearer on reading the following description, which refers to the attached drawings.

### BRIEF DESCRIPTION OF THE DRAWINGS

Other characteristics and advantages of the invention will become clearer on reading the following description, which refers to the attached drawings, wherein:

FIG. 1 shows the circuit diagram of a miniature power supply according to the invention;

FIG. 2 schematically shows the overall structure of a miniature power supply according to the invention;

FIG. 3 shows the structure of a cell constituting the heat taking-up and conversion into the light energy layer;

FIG. 4 shows the lay-out of a plurality of cells which constitute the heat taking-up and conversion into the light energy layer;

FIG. 5 is an energy-level diagram showing the energy-levels of n-type and p-type semiconductors in comparison with the Fermi level of the metal;

FIG. 6 schematically shows structure of the conventional cooling plates in which the Peltier effect is used;

FIG. 7 is a specific graph showing the relationship between the quantum yield Ym and the wavelengths of a photocathode made from GaAsP—Cs—O;

FIG. 8 is a specific graph of a photocathode made with silicon showing between the relationship of the quantum efficiency and wavelengths of light when the light is reflected to the photocathode;

FIG. 9 shows the reflection state of the light at a photocathode surface made of silicon; and

FIG. 10 is a graph showing the relationship of the taking-up heat efficiency ε and the temperature difference ΔT between two surfaces of a taking-up heat plate.

### DETAILED DESCRIPTION OF THE PREFERRED EMBODIMENT

The structure of a miniature thermal-photoelectric power supply in the preferred embodiment of the present invention is the form of a thin plate comprising a plurality of layers which are bonded sequential as follows:
a latent heat layer or also known as the heat energy storing layer;
a heat taking-up and conversion into the light energy layer is bonding to said heat energy storing layer, and comprises: a taking-up heat layer over which a layer for converting the energy of the circuit in said miniature power supply into light, a layer for converting the light into electric energy including a photoelectric cell plate, and a heat radiation layer. All of above mentioned layers are encased within a protection housing. The miniature thermal-photoelectric power supply according to the present invention is provided with two input terminals for charging while these terminals are connected to an external power source, and the charged electric energy is converted into the heat energy in said latent heat layer, two output terminals are to output a current from the photoelectric cell plate. The output circuit of the miniature power supply is divided into two output circuits, one for the circuit of a mobile device and the other for the inside circuit within the miniature thermal-photoelectric power supply. Also, a circuit is provided in parallel with two said output circuits, wherein one capacitor is provided with function of a given electric discharge for initiating the miniature power supply once it starts to operate. After a discharge to assist the miniature power supply in starting, this initiating circuit will be recharged to recover the initial state of the capacitor, thereby it is ready to bring the miniature power supply according to the present invention into operation after each Off-On period. Said initiating circuit is switched off as soon as the capacitor was charged fully and switched on when starting operation of the miniature power supply. Entire circuits of the miniature power supply are schematically shown in FIG. 1.

FIG. 1 is a circuit diagram of the miniature power supply according to the preferred embodiment, wherein showing the arrangement between the inside circuits of the miniature power supply and the output circuit for supplying to a mobile device. In FIG. 1, the inside circuits of miniature power supply comprise: the photoelectric cell plate 1; the circuit 2 of the taking-up heat and converting electric energy into light layer; the circuit 3 of the heat-absorption layer, wherein the energy is stored in the form of heat energy; the output circuit 4 for outputting electric to a mobile device; and the electric energy stored circuit 5 is used for initiating the miniature power supply. As will be appreciated, the circuit of said heat-absorption layer is a self-contained circuit which is connected to an external power source while charging of the power supply. The photoelectric cell plate 1 acts as power source in order power to a plurality of circuits which are in connection with each other comprising:
The output circuit 4 of a mobile device.
The circuit 2 of said taking-up heat and converting electric energy into light layer.
The initiating circuit 3 in which the electric energy is stored for use in initiating the miniature power supply by switching off this circuit when said capacitor is charged fully and switching on once starting operation of the miniature power supply.

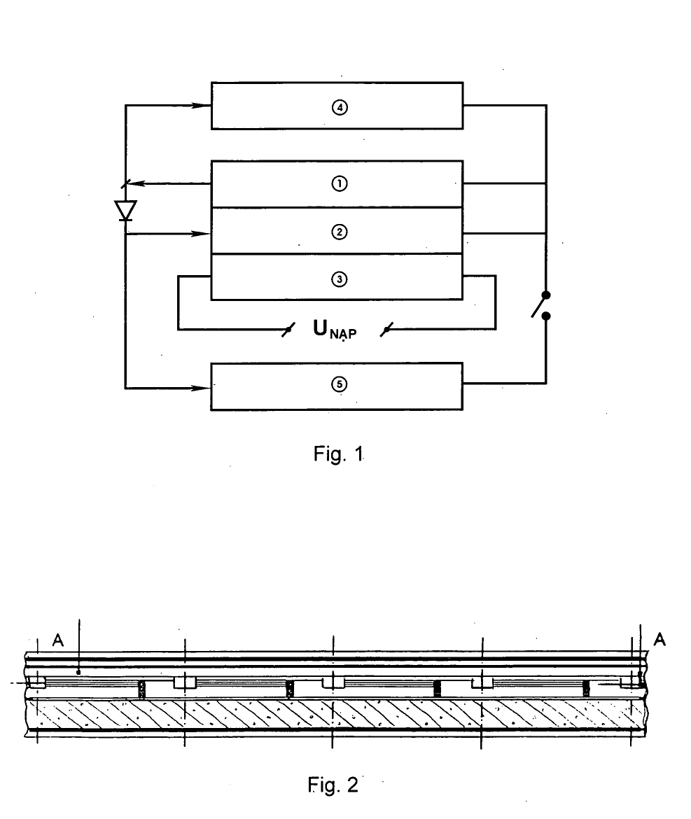

The miniature thermal-photoelectric power supply according to the present invention comprising a bonding structure between a plurality of layers as shown in FIG. 2.

The following will be the detailed description of the structure and function of above-mentioned layers by reference to the attached figures.

1. Heat-Absorption Layer

As discussed above, in an important aspect of the present invention, the miniature thermal-photoelectric power supply should be provided with an adequately high energy amount in the form of heat energy for use in a converting heat energy into light energy process and eventually, in a converting light energy to electric energy process for supplying to the loading circuit of a mobile device for an extended period of time, while the dimensions as well as the weight of this power supply should be small enough in order to satisfy the need of a compact and lightweight mobile device. In accordance with the invention, the latent heat layer comprising a closed chamber in thin plate shaped with a thickness is about 1 mm, and containing CO₂ gas in critical state. As well known in the art the property of CO₂ gas in the critical state (where the critical temperature T_{TH}=31.15+ C.; the critical pressure P_{TH}=7.387 MPa; the critical specific weight m_{TH}=0.468 g/cm³) is similar to that of other gases in critical state in that it has an extremely high heat-absorption capacity (in theory, at critical point, the heat-absorption capacity of these gases will reach to infinite value). Thus, it can be introduced into the thin chamber containing CO₂ gas in critical state a high heat amount as required. In this closed chamber there is a metal net which will be highly heat radiated while a current runs through it. During charging for the miniature power supply, a current is fed to metal net and at its outer surface, the supplied electric energy is converted into heat energy. The entire calorific energy will be absorbed by CO₂ gas in critical state while the temperature and pressure of CO₂ gas in the closed chamber remain unchanged, i.e. (dP/dV)_{T}=0 and (d²PdV²)_{T}=0. As discussed above, because the heat absorption capacity of CO₂ gas in critical state in the heat storage chamber is infinite, a calorific energy level which is high enough can be charged into energy storage chamber. Thereby, it is possible to make an electric energy level which is adequate to the electric demand of a mobile device for a long operation period of time as required. Furthermore, the charging period of calorific energy in the miniature power supply is relatively short since it is not depending on chemico-physical conversion process which occurs very slowly as the charging process of the conventional batteries. In the preferred embodiment of the invention, CO₂ gas is selected as the heat absorber because it has the suitable critical temperature, very cheap and moreover, CO₂ gas does not reacts with oxy at a high temperature in case a leakage occurs.

2. A Heat Taking-Up and Conversion into the Light Energy Layer

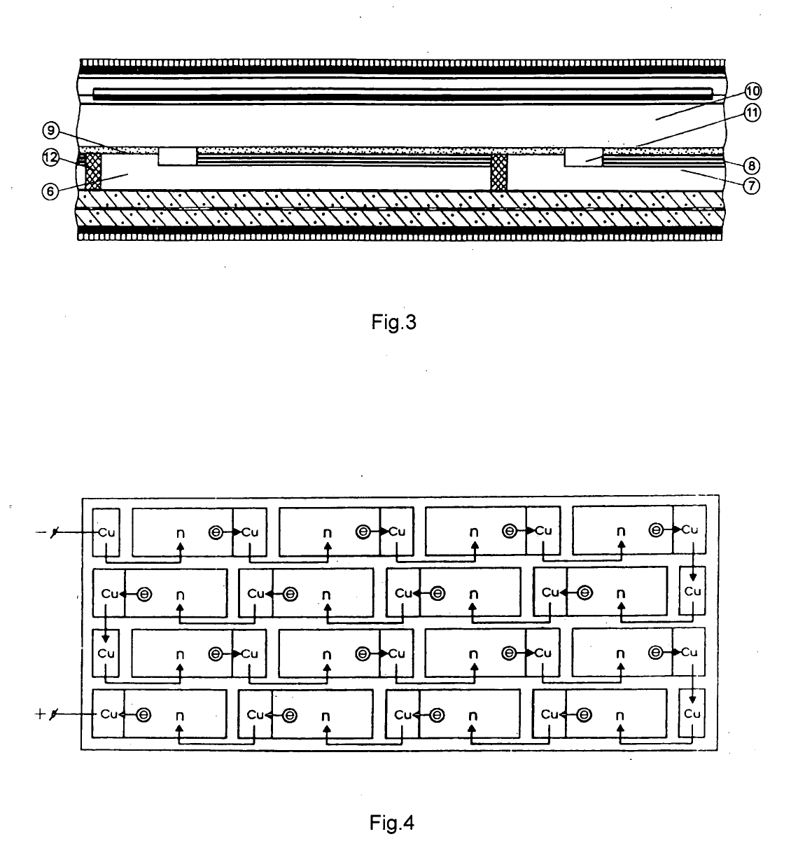

A heat taking-up and conversion into the light energy layer comprising a heat-absorption layer and a converting energy into light layer. This heat taking-up and conversion into the light energy layer is a thin plate bonded with said heat-absorption layer. Between these two layers there is a very thin coating made from a material which has high electric insulation and high thermal conduction capacities. In this case, MgO or Al₂O₃ can be used as material of the coating. Said thin plate comprising a plurality of identical closed cells which are configured in a series circuit. The typical structure of each series-connected cells of the heat taking-up and conversion into the light energy layer is shown in FIG. 3. In FIG. 3, each said cell comprises the copper electrode 1 acts as a substrate of the heat-absorption layer, as discussed below, the n-type semiconductor layer 8 is a laminate constituted of a plurality of membranes, the inert gas layer 9, the protection layer 10 of the electrode plates is made of an electric insulator material, the thin quartz plate 11, the partition 12, and the insulating partition 13 interposed between two electrode plates.

In accordance with the invention, each cells comprises the electrode or base 7 is an conducting laminate made in contact with said heat-absorption layer and functions to take up heat, and an upper layer in which the flow of electrons releases the energy of the entire circuit (including the current energy of supplied input current and the thermal energy just taken up by the current) as light energy. The arrangement of said series cells on the bonding surface between two layers is shown in FIG. 4. FIG. 4 is a cross-section view illustrating the arrangement of cells in the miniature thermal-photoelectric power supply taken along line A-A in FIG. 2. As can be seen in this drawing, the flow of electrons ©→ during discharging, flows through a plasma gas, and the flow of electrons → moving from the copper substrate to n-type semiconductor layer.

The typical structure and function of each functional layer in each cells will be described below.

2.1 Heat-Absorption Layer

Heat-absorption layer constitutes of a part of the electric circuit of each cell and it has a junction structure between copper electrode layer also as the substrate of the heat-absorption layer 7 with n-type semiconductor layer 8 consists of a plurality of membranes made from Bi₂Te_{(3-X)}Se_{X}. At the bonding junction, when a flow of electrons flows from the copper substrate to said n-type semiconductor layer, a phenomenon occurs in which the heat energy is taken up from the bottom surface of the copper substrate which is in contact with the heat-absorption layer. This phenomenon is known in the art as Peltier effect in which, when an electric current is passed through a junction consisting of wires of different metals, in addition to Joules effect, the junction will be warmed or cooled depending on the direction of current flow. In particular, when a current flows through the junction, heat will either be absorbed or evolved depending on the direction of current flow. The calorific energy is defined by the equation:
Qₚ=P.I.t (1)
where
Qₚ is the calorific energy which will be absorbed or evolved at the junction;
I and t are the current and the time, respectively; and
P is Peltier constant of the conducting couple.

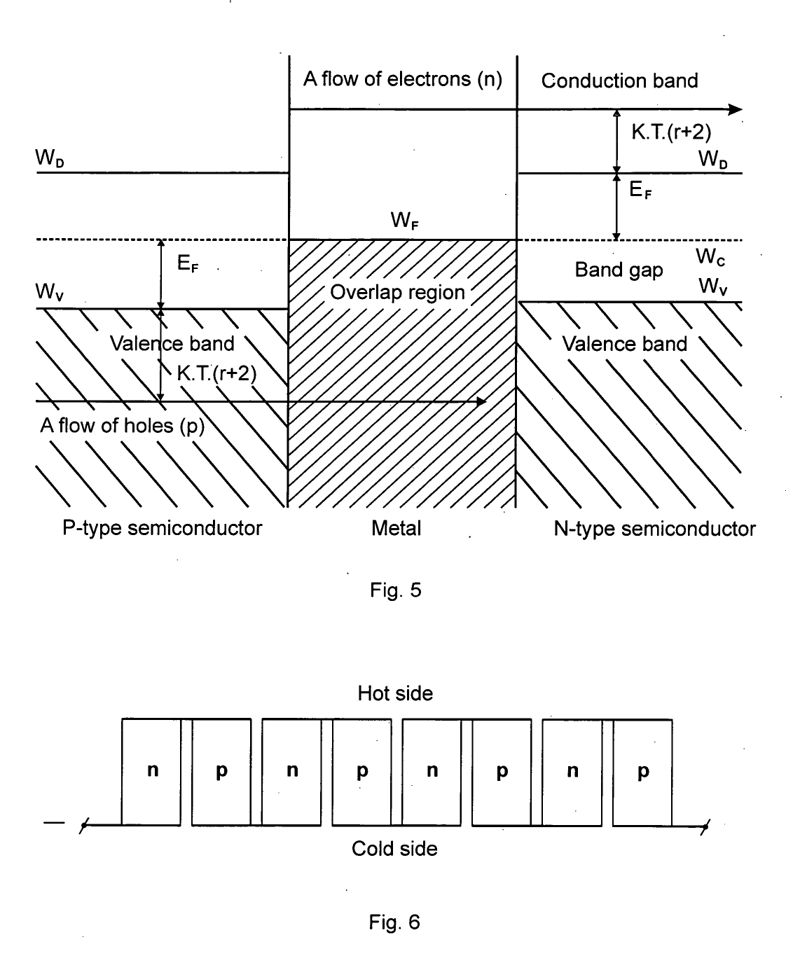

The heat absorption occurs in Peltier effect at bonding junction of the heat-absorption layer when there is a flow of electrons flows from the copper substrate to n-type material membrane also can be seen clearly in FIG. 5. FIG. 5 illustrates the energy level diagram of n-type and p-type semiconductors in comparison with Fermi level of metal, wherein:
W_{F}—Fermi level of metals.
W_{D}—Energy level of the conduction band.
W_{C}—Energy level of the band gap.
W_{V}—Energy level of the valence band.

It looks like this:

E=(W_{D}−W_{F})+K.T.(r+2) is energy which taken by an electric charge when it passes from metal to n-type semiconductor or released when it passes in opposite direction.

E=(W_{F}−W_{V})+K.T.(r+2) is energy which is released by a hole when moving from metal to p-type semiconductor or taken when moving in opposite direction.

This heat absorption can be analyzed based on the quantum theory as described below.

Since the energy level of conduction band W_{D} of n-type semiconductor is higher than that of metal W_{F}, an electron of metal must raise its energy level in order to cross the band gap W_{C} and becomes a free charge carrier. The energy which was taken by a flow of electrons when moving from the metal to n-type semiconductor is energy which is lost at the junction, thereby making the temperature of junction sinks. At surface of the copper substrate contacting with heat-absorption layer, there is occurrence of the temperature difference and the thermal transfer occurs from heat-absorption layer to the copper substrate for compensating said calorific energy which was taken by the flow of electrons when flowing across from the junction to n-type semiconductor. As described above, in relation with the working principle of miniature thermal-photoelectric power supply, an important demand is the heat-absorption layer of the miniature power supply should be capable of taking-up heat adequately for supplying energy to the circuits in the processes of heat into light conversion and light into electric energy conversion, thus powering to the initiating circuit of the power supply and the load circuit of a mobile device. Heat taking-up rate of heat-absorption layer of the miniature power supply is depending directly on the cooling efficiency at bonding junction between the copper layer and n-type semiconductor. As known in the art, this cooling efficiency at bonding junction is a rate between the taken energy level and the electric energy level supplied to the bonding junction, particularly:
ε=Q_{L}/Q_{I} (2)
where
ε is the cooling efficiency at bonding junction;
Q_{L} is the taken energy level; and
Q_{I} is the electric energy level supplied to the bonding junction.

Generally, a Peltier cooling plate comprises the junction welded structure consisting of n-type and p-type semiconductor couples alternately connected in series as shown in FIG. 6. In FIG. 6, when a current runs from n-type semiconductor across the junction with the thin copper layer then to the bonding junction with p-type semiconductor, the surface of copper layer will be heat-absorbed by n-type and p-type semiconductor bars and becomes colder while at opposite surface of the cooling plate, the current runs from p-type semiconductor bar through the copper layer and to n-type semiconductor bar so that the supplied energy current and the taken up energy are emitted at the junction of copper plate, thus make it hotter. The cooling plates which have been manufactured by the conventional technologies generally have relatively large dimensions in which semiconductor bars provided with height in the range of 2 to 3 mm, thus their resistance are relatively high. As already known in the art, the cooling efficiency ε of such cooling plates just are about 0.7. Today, however, in latest technologies, Peltier cooling plates are manufactured with n-p type semiconductors which made from the material consists of Bi, Te, Sb and Se. These plates are in the form of thin layer with a thickness of several tens of nanometers and are bonded in a plurality of layers in which each layer including a given composition and the thermal emf e of each layer is designed appropriately. Such thin plates have the cooling efficiency ε very high, i.e. about 1.6 (more than 2 times greater than those of the prior art cooling plates). By applying the membrane bonding engineering to manufacture the heat-absorption layer of the miniature thermal-photoelectric power supply in accordance with the invention, this cooling efficiency can be improved further since the energy which is taken up by n-type material membrane will be released as light but not emitted at the junctions on a hot side thus causes the heat accumulation state and decrease the cooling efficiency as conventional cooling plates. In miniature thermal-photoelectric power supply, the temperature of the surface of n-type semiconductor layer is not increased too much. The influence of the temperature difference between two surface of cooling plate on its cooling efficiency is expressed in the following equation:
εₘₐₓ=(MTₒ−T)/ΔT.(M+1) (3)
where:
T, To, ΔT (K) are temperatures of the hot and cold sides of cooling plate and the temperature difference between them, respectively;
M—the cooling constant which is calculated as follows:
   M={1+0.5*Z*(T+Tₒ)}^{1/2} (4)
   where Z=e²/K*R (5)
   with Z is a specific cooling constant depends on each cooling plate,
e is a specific thermal emf of each cooling plate,
R is the resistance of the cooling plate, and
K is Boltzmann constant.

In the equation (3), the cooling constants M and the specific cooling constants Z of the cooling plates are substantially the same in each cooling plates and these parameters do influence inconsiderably to the cooling efficiency ε, so that the value of the maximum cooling efficiency εₘₐₓ of plates will be increased much when the temperature difference ΔT decreases. FIG. 10 is a diagram illustrates the relationship between cooling efficiency ε of cooling plates and the temperature difference ΔT between their opposite sides. As can be seen in this drawing, when the temperature difference between the opposite of the cooling plate lowers, the cooling efficiency increases dramatically. Specifically, the taking-up heat efficiency of the miniature thermal-photoelectric power supply according to the present invention can be made to reach: ε≧1.6.

2.2 Converting Energy into Light Layer:

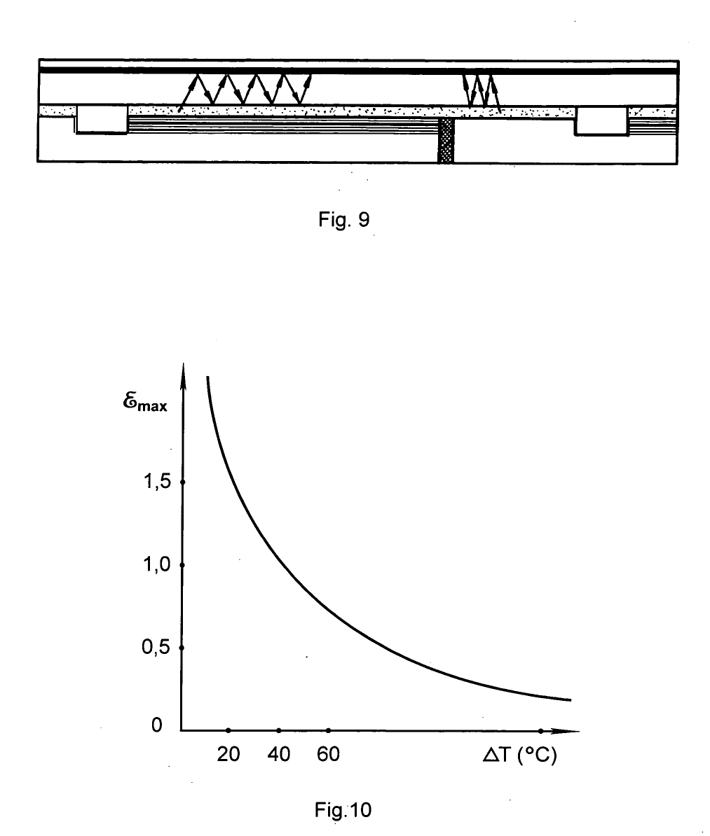

Within each cells of the inside circuit of the miniature power supply, the converting energy into light layer is a thin chamber with a thickness of approximate 0.1 mm containing a rare inert gas includes a degree of ionization of about 10⁻⁶. Such inert gas layer is contacting with the surface of n-type material membrane and the copper electrode layer. Between the n-type material membrane and the copper electrode layer a partition is provided with high insulating capacity. After taking up a given calorific energy during moving from the copper substrate across the junction with n-type material membrane, the flow of electrons continuing to discharge through the inert gas layer to the copper electrode layer. In the inert gas layer, because the electrons have a very low energy level they release the redundant energy as the quantum energy. The luminescence property when discharging through the inert gas is known as Plasma phenomenon, this phenomenon can be used in many industry applications. Wavelength of emitted light in this case is depending on the typical inert gas employed, the gas pressure within the chamber and the current density discharging through gas layer. In order to improve the quantum yield of the converting quantum energy into electric energy process at the photoelectric cell, the emitted light should have a wavelength as low as that of ultraviolet, i.e. in the range of 400 to 200 nm with the quantum energy level W_{λ}=3.1÷6.2 eV. In accordance with the invention, the inert gases such as Ne, Xe, Ar or Kr with the pressure of chamber in the range of 0.05 to 3 atms for the light beams have the following wavelengths, particularly: Xe, λ=370 nm; Ne, X=240÷250 nm; Ar, λ=215÷230 nm and Kr, λ=220÷250 nm in a period of time approximate 20 nano seconds. The converting current into light efficiency of plasma is very high, about 0.98. To prevent the electrode plates from damaging by electrons and ions during discharging, the surface of the electrode plates can be coated with a coating membrane sized very thin, with a thickness is about several hundreds nanometers, typically made of a material which is strong insulating material. This solution is an used commonly process in manufacturing the plasma monitors. By such an insulating coating on the surface of electrode plates, each cell of the miniature power supply becomes a capacitor. Because the insulating layer has a thickness of about several nanometers a voltage of some Volts (i.e. higher than the breakdown voltage of capacitors) is appeared between two leads of the inside circuit of the miniature power supply, said capacitors can be “broke down” and an electron flow passes across insulating membrane to go through the gas layer towards the copper electrode. With the circuit structure of capacitors (it can be integrated into the bus of the inside circuit of a mobile device), a high frequency current 50 MHz can be generated in the inside circuit of the miniature power supply with the discharging time through the gas layer is about 20 nano seconds as required. The side of chamber containing gas is a thin quartz plate since the quartz material enables the ultraviolet to pass up to 99.9%. Relative to the ultraviolet, since plasma gas having a refractive index n in the range of 1.0002827 to 1.0003240 while the refractive index n of quartz is in the range of 1.55716 to 1.63039 an additive can be added into the quartz material to increase the refractive index of quartz for generating a reflection effect at the contact surface between said quartz plate and the plasma gas, whereby the light, after going through quartz, reflects to the gas layer and returns to the surface of photoelectric cell for improving the quantum absorption yield of the cell. The reflection state of light beam to returns photoelectric cell is illustrated in FIG. 9. FIG. 9 shows the reflection of the light beam from plasma gas layer to the silicon surface. A light portion is reflected at this silicon surface before reflecting again to the contact surface of quartz and plasma gas since the refractive index of quartz which has been added an additive is much more than the refractive index of plasma gas.

2.3. The Absorbing and Converting Light into Electric Energy Layer

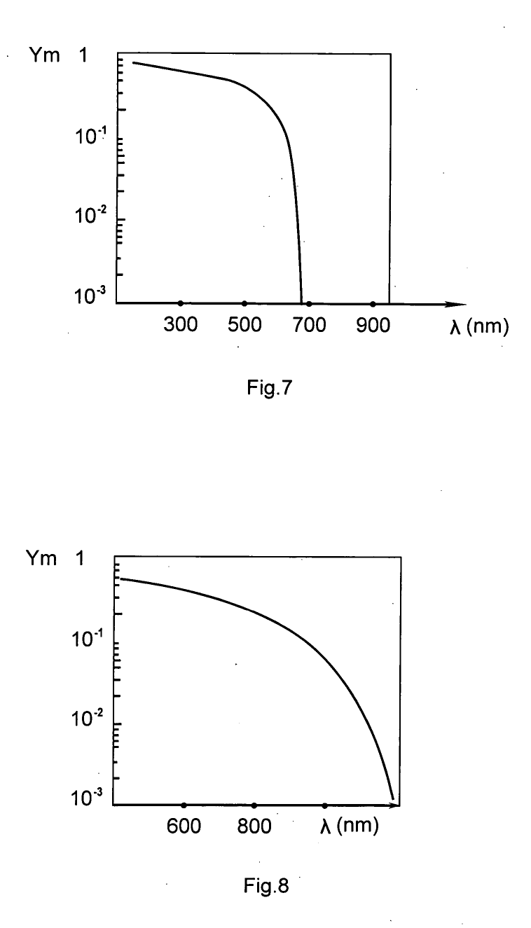

The absorbing and converting light into electric energy layer is a photoelectric cell plate which is bonded on surface of quartz layer. Ultraviolet light is radiated to this photoelectric cell to generate more charge carrying elements in the semiconductor layer of photocathode. The production process of said charge carrying elements requires a given energy to enable electrons to pass through the band gap of the semiconductor constituting photocathode. To let the miniature thermal-photoelectric power supply operate, said photoelectric cell should be capable of highly absorbing-light. The light absorption capacity of photoelectric cell is defined by the quantum yield of photocathode. This quantum yield is depending on the number of hole-electron pairs which can be produced by one quantum. The light absorption capacity of photoelectric cell in the miniature thermal-photoelectric power supply is not allowed to be lower than 0.5 for generating the electric energy which is enough for satisfying the demand of the initiating circuit of the power supply and the load circuit of a mobile device. Since the photoelectric cell of miniature power supply is too small the GaAsP—Cs—O material can be selected as the material of the photocathode while its. cost is very expensive. GaAsP—Cs—O material has a quantum yield very high: Ym=0.5 with the limited wavelength: λₒ=680 nm. The relationship of this quantum yield Ym and wavelengths will follows the equation:
Ym≈(h.c/λ−h.c/λₒ)^{m} (6)
where m=1÷3 depends on absorption type of electric energy regions (i.e. the absorption efficiency of energy region to self-conduction energy region in photoelectric effect, the transient absorption between allowed energy regions of charge carrying elements and the absorption by the impurity center in the band gap). The quantum yield substantially depends on the light wavelength of GaAsP—Cs—O material as shown in FIG. 7. The diagram in FIG. 7 illustrates the relationship between the quantum yield Ym and the wavelength of light X at the photocathode surface which is made from GaAsP—Cs—O material.

By analyzing the diagram in FIG. 7 and equation (6), it will be understood that in relation with the ultraviolet beam, the quantum yield Ym is more than 0.5 and this quantity can reach to a value in the range of 0.6 to 0.65. Since the cost of GaAsP—Cs—O material, however, is very expensive there is a limitation of its application in manufacturing the photocathode of photoelectric cell in the miniature thermal-photoelectric power supply. According to the present invention, an alternative solution is to employ the silicon as material of the photocathode in the miniature power supply with the reflection structure at a contacting surface between said plasma gas and quartz layers into which a specific additive has been added as discussed above in order to increase the quantum yield of silicon. FIG. 8 is a diagram showing the relationship between wavelengths of light and quantum yield at the photocathode surface which is made of silicon when the surface is reflective radiated as shown in FIG. 9.

2.4 Heat Radiation Layer for Cooling the Photoelectric Cell Plate

At the photocathode surface, there is a light energy portion is not converted into the electric energy but the heat energy which can make the photoelectric cell plate to be hot. The absorption efficiency of photoelectric cell can be affected if its temperature raises. Therefore, the photoelectric cell plate should be cooled for the whole operation period. For this purpose, there is interposed a very thin copper coating between the top face of the photoelectric cell plate and the bottom face of heat-absorption layer, this coating is over outer face of the miniature thermal-photoelectric power supply. The copper coating acts as a material capable of highly heat transfer from the photoelectric cell plate to heat-absorption layer once a temperature difference occurring between those surfaces to keep the cell plate from being hotter over 35° C. The cooling process for the photoelectric cell plate in the same time serves as a heat recovery process of said energy storage layer.

Based on above-mentioned parameters of each elements or parts of the miniature thermal-photoelectric power supply, the power capacity of the present power supply can be calculated according to a simplified equation as follows:
Wₒᵤₜ=Wᵢₙ*(ε+1)*P*N_{Q} (7)
where
Wᵢₙ is the energy level is supplied to the power supply;
W_{Out} is the energy level which is generated by the miniature power supply according to the present invention;
ε is the cooling efficiency or the taking-up heat efficiency of the miniature power supply, ε=1.6;
P is the energy releasing efficiency of the plasma gas, P=0.98;
N_{Q} is light absorption capacity of the photoelectric cell, N_{Q}=0.60÷0.65.

Thus:
Wₒᵤₜ=W_{in*}(ε+1)*P*N_{Q}=Wᵢₙ.(1.6+1)*0.98*(0.60÷0.65)

As a result, Wₒᵤₜ=(1.53÷1.66). Wᵢₙ

Therefore, the output energy from the output of the miniature thermal-photoelectric power supply is sufficient for supplying to both its operation and that of a mobile device. The electric energy quantity is used for supplying to the circuit of mobile device is in the range of 0.53÷0.66 times of the energy level which is used for the power supply.

### AN EXAMPLE OF PRESENT INVENTION

Next, an example of the present invention will be described as a new power supply for mobile phones. In the conventional mobile phones, their batteries generally have dimensions: 4×3×0.4 cm with a voltage U of 3.6V and current capacity I is in the range of 600 to 1000 mA.h, i.e. the electric storage capacity W is in the range of 2.16 to 3.6 W.h. These parameters are sufficient to secure the energy supply to mobile phones for operation period in the range of 1.5 to 3 hours of continuous talking. The needed time for charging said batteries generally more than 3 hours, and for other batteries, this charging time can be increased up to 8 hours. The miniature power supply in accordance with the invention is designed for supplying electric energy in order to enable the mobile phones to operate for 20 continuous talking hours, thus it should be restored with a calorific energy which is corresponding to the energy level of approximate 30 W.h. As discussed above, dimensions of the miniature thermal-photoelectric power supply do not depend on the calorific energy which is needed to charge. The charging period for such calorific energy is not longer than 30 minutes. To supply an electric energy level of about 1.5 W.h, with a rate between the output and input energy levels of miniature power supply: Nw≈1.5 to a mobile device, the miniature power supply is required to have the input energy level Wᵢₙ=3 W.h, with the taking-up heat efficiency ε=1.6, the heat energy level which can be taken up is approximate 4.8 W.h, and the energy level which can be released at the plasma gas layer is approximate 7.8 W.h. With the energy releasing efficiency of plasma gas P=0.98, the light energy level of radiated light on the photoelectric cell plate is about 7.64 W.h. On photoelectric cell plate, as will be appreciated that an energy light level in the range of 60 to 65% can be absorbed and converted into the electric energy, at output of the miniature thermal-photoelectric power supply there can be an electric energy level for supplying to the power supply and to a mobile device: WOut in the range of 4.6 to 5 W.h. Dimensions of the miniature power supply just depend on the heat-absorption layer and photoelectric cell plate, in the light of the data in the art, in which the cooling plate can be produced by bonding a plurality of membranes which have the cooling efficiency up to a several hundreds of W/cm². Furthermore, heat conducting capacity between the taking-up heat plate and the heat-absorption layer also can be calculated as follows:
the temperature difference between heat-absorption layer and the substrate of taking-up heat plate is not below 10° C. and with heat conducting capacity of insulating membrane Al₂O₃ is about 40 W/(m.° C.), through the thin layer with a thickness about 1 mm, there is a heat flux which can be transferred at density of 40 W/cm². In comparison with the energy level which is needed to be taken up in the miniature power supply of 4.8 W, based on above calculations, it can be understood that the dimensions of miniature thermal-photoelectric power supply for the mobile phones only depend on the their manufacturing technologies. Thus, the miniature power supply can be produced with a surface area is smaller than 1cm², a thickness is thinner than 2 mm and the weight is just a several grams. This miniature thermal-photoelectric power supply is specially compact and its storage capacity is sufficient for supplying to mobile phones for long periods.
   The Effect of the Present Invention

The miniature thermal-photoelectric power supply in accordance with the invention serves as a power source for mobile devices wherein this power supply has a large storage capacity but compact structure, while the conventional batteries have disadvantages in that their storage capacity are not large and structures are too heavy and bulky.

1. A miniature thermal-photoelectric power supply comprising:
a heat energy storing layer, said heat energy storing layer being a thin chamber containing gas CO₂ in critical state, wherein a metal net which is capable of highly heat-radiating is disposed within gas CO₂ in said chamber during a thermal energy charge process by connecting to an external power source;
a heat taking-up and conversion into light energy layer is coupled to said heat energy stormg layer for taking-up and converting heat energy stored in said heat energy storing layer into electric energy, said a heat taking-up and conversion into light energy layer comprising:
a taking-up heat layer including a welded joint interposed between a copper substrate and a plurality of membranes of a n-type sericonductor, wherein due to Peltier effect, when a flow of electrons is passed from the copper substrate to the n-type matial membranes, the junction is warmed or cooled depending on the direction of the flow of electrons, particularly, the temperature of copper substrate is lowered since the electrons absorb the energy from the junction and pass across the band gap of n-type seniconductor, and by means of a temperature difference between the copper substrate and the heat-absorption layer, a heat flow flows from the heat-absorption layer with a higher temperature to the copper substrate which emits heat continuously,
a converting supplied electric energy and taken-up energy into light layer includes an inert gas layer contained in a thin chamber such that when a flow of electrons flowing from n-type material membranes discharge across the inert gas layer to copper electrode, Plasma phenomenon occurs wherein energy of electrons in the gas layer which is much lower than energy level at the conduction band of n-type semiconductor will be dropped to a lower energy level, thereby the energy of electrons wil be converted into the light enegy;
a thin quartz plate acts as a lid of said inert gas chamber to enable the light to pass through;
a photoelectric cell plate coupled to said thin quartz plate for receiving and converting the light into the electric energy which will be supplied to an external load device; and
a cooling layer of photoelectric cell plate simultaneously serves as a heat recovery layer.
